(19) United States
(12) Patent Application Publication
(10) Pub. No.: US 2007/0256729 A1
(43) Pub. Date: Nov. 8, 2007

(54) Light-Assisted Electrochemical Shunt Passivation for Photovoltaic Devices

(75) Inventors: Aarohi Vijh, Sylvania, OH (US); Xunming Deng, Sylvania, OH (US)

Correspondence Address: MACMILLAN SOBANSKI & TODD, LLC, ONE MARITIME PLAZA FIFTH FLOOR, 720 WATER STREET, TOLEDO, OH, 43604-1619, US

(73) Assignee: THE UNIVERSITY OF TOLEDO, Toledo, OH (US)

(21) Appl. No.: 11/578,359

(22) PCT Filed: Apr. 15, 2005
(86) PCT No.: PCT/US05/12777

§ 371 Date: Mar. 20, 2007

Related U.S. Application Data
(60) Provisional application No. 60/563,132, filed on Apr. 16, 2004.

(51) Int. Cl. H01L 31/00

(52) U.S. Cl. 136/252; 136/261; 29/730

(57) ABSTRACT

A method of passivating current-shunting defects in a photovoltaic device and such passivated photovoltaic devices are described. The photovoltaic device includes a thin film body with a superposed electrode comprised of a layer of transparent electrically conductive electrode material. The method includes converting the transparent, electrically conductive electrode material to a material having a higher electrical resistivity than the transparent electrically conductive electrode material or by removing the transparent conducting electrode material, by simultaneously: 1) immersing at least a portion of the electrode in a conversion reagent, 2) illuminating the immersed electrode with a suitable source of illumination, and 3) applying an appropriate electrical bias to activate the conversion.

### CROSS-REFERENCE TO RELATED APPLICATIONS

This application claims the benefit of U.S. Provisional Application No. 60/563,132, filed Apr. 16, 2004, the disclosure of which is incorporated herein by reference.

This invention was made with Government support under AFRL-Kirtland “Lightweight and flexible thin film solar cells based on amorphous silicon and cadmium telluride” under contract F29601-02-C-0304 and National Renewable Energy Laboratory “High efficiency and high rate deposited amorphous silicon solar cells” under contract NDJ-2-30630-08. The government has certain rights in this invention.

### FIELD OF THE INVENTION

The present invention is generally directed to solar cells (photovoltaic devices) in general, and particularly to a process for passivating or isolating short circuit current paths which form in amorphous/microcrystalline silicon thin film photovoltaic devices.

### BACKGROUND OF THE INVENTION

Photovoltaic devices that include the use of thin film amorphous/microcrystalline Si and Ge alloys are now routinely produced by glow discharge (plasma) chemical vapor deposition processes. For example, a photovoltaic device may be fabricated by passing a stainless steel web through a succession of chambers, each depositing one kind of thin film semiconductor layer to form a “thin film semiconductor material”.

Thin film semiconductor materials offer several distinct advantages over crystalline materials, insofar as they can be easily and economically fabricated into a variety of devices by mass production processes. However, in the fabrication of semiconductor materials and photovoltaic devices by glow discharge, or other chemical vapor deposition processes, the presence of current-shunting, short circuit defects has been noted. These defects seriously impair the performance of the photovoltaic devices fabricated therefrom and also detrimentally affect production yield. These process-related defects are thought to either be present in the morphology of the substrate electrode, or to develop during the deposition or subsequent processing of the semiconductor layers.

Shunt defects are present in photovoltaic devices when one or more low resistance current paths develop through the semiconductor body of the device, allowing current to pass unimpeded between the electrodes thereof. Under operating conditions, a photovoltaic device in which a shunt defect has developed, exhibits either (1) a low power output, since electrical current collected at the electrodes flows through the defect region (the path of least resistance) in preference to an external load, or (2) complete failure where sufficient current is shunted through the defect region to “burn out” the device.

Several approaches to reduce the deleterious effects of these short circuit paths have been described in: U.S. Pat. No. 4,451,970, U.S. Pat. No. 4,464,823, and U.S. Pat. No. 4,419,530 to Nath; and U.S. Pat. No. 4,598,306 to Nath, et al. Also, recent publications by Karpov et al. describe a method to passivate shunts in appropriate thin film solar cells. Roussillon, Y.; Giolando, D. M.; Shvydka, Diana; Compaan, A. D.; Karpov, V. G., “Blocking thin-film nonuniformities: Photovoltaic self-healing”, Applied Physics Letters, Vol. 84, Issue 4, Jan. 26, 2004.

Also, the Weber U.S. Pat. No. 5,055,416 describes anodic etching of exposed portions of a metal layer after deposition of amorphous silicon and prior to depositing a transparent conductive layer.

The Swartz, U.S. Pat. No. 4,385,971 describes that the rectifying junction of solar cells should be in reverse bias during any electrolytic etch in order to cause the electrical current to flow only through the short. Therefore, in order to etch a stainless steel/p-i-n/ITO structure according to Swartz, the stainless steel should be connected to a negative terminal of a DC source. 20% ammonium hydroxide is employed as an electrolyte. Swartz also teaches etching a stainless steel/N—I/platinum Schottky barrier type cell by connecting the stainless steel layer to the positive terminal of a DC source and immersing it in an electrolyte solution of dilute sulfuric or copper sulfate.

There are also several teachings against applying a forward bias to semiconductor devices. Izu et al. U.S. Pat. Nos. 4,510,674 and 4,510,675, describe using a reverse bias over forward bias for detecting shorts in a solar cell. Izu et al. describe that, in forward bias, forward conduction is thought to decrease the ability to distinguish a shorted area from an acceptable area of a cell. The Izu et al. '674 describes applying a reverse bias to a device to detect the presence and location of a short circuit current path is actually preferred. The Izu et al. '674 described that when a device is biased in the forward direction, there is the possibility that the device could go into forward conduction; and that this condition, which resulted in a sharp rise in current, could be mistaken by a current threshold detector for the presence of a short circuit current path. The Izu et al. '674 described that, however, this is not possible with the reverse bias condition; and as a result, for detecting the presence and location of a short circuit current path, reverse bias is preferred.

The Kawakami U.S. Pat. No. 5,320,723 describes that when the electrolyte solution is an aqueous solution, the voltage applied is preferably not lower than 1.23V which is the stoichiometric decomposition potential of water under the standard condition of 25.degree. C. at 1 atm. Kawakami et al. stated that the application of too high a voltage, however, tends to cause side reactions at portions other than the short-circuit portion to be treated.

The above Swartz '971, Izu et al. '674 and Kawakami '723 patents refer to the problem of unwanted isolation of unshunted portions of a solar cell due to application of a forward bias voltage for shunt passivation, which can cause current flow in unshunted portions of the solar cell, in addition to the shunted regions. However, this does not alter the fact that there exist electrolytes/electrochemical systems that are extremely effective in converting the offending electrode portions into insulators under what turns out to be a forward bias for the solar cell (e.g., the process described in the Nath et al. U.S. Pat. No. 4,729,970 applied to a-Si n-i-p, substrate type solar cells using AlCl₃ electrolyte).

Therefore, what is needed in such cases is a method to cancel or reduce the forward bias in unshunted regions of the cell. The present invention achieves this by illuminating the front surface of the cell with light of suitable wavelengths and sufficient intensity. The natural photovoltage produced by the unshunted regions of the illuminated cell then fully or partly cancels out the unwanted forward bias, thus preventing or minimizing the unwanted conversion of the ITO. Thus, the selectivity of the conversion process is enhanced.

The Ichinose et al. U.S. Pat. No. 6,221,685 describes, and shows in FIG. 2B therein, the electric field can be generated by irradiating the photovoltaic element in the electrolyte solution with light; in this case, the photovoltage itself of the photovoltaic element generated by light irradiation acts as an applied bias voltage.

The Ichinose et al. U.S. Pat. No. 5,859,397 describes that the electric field used in their invention may be either an electric field generated by impressing a bias power to the photovoltaic element or an electric field generated by an electromotive force of the photovoltaic element which is generated by irradiating light to the photovoltaic element.

The above Ichinose et al. '685 and '397 patents mention that light alone may be used to generate the voltage bias required for electrochemical shunt passivation.

However, the inventors herein have found that the rate of the passivation reaction is unacceptably slow, at least for triple-junction amorphous silicon solar cells using ITO as the front contact, if light alone is used to generate the electrical bias. For single- and double-junction a-Si cells, the passivation reaction may not proceed at all, since the photovoltage produced by these types of cells lower than that produced by triple junction cells.

Also, the Nath et al., U.S. Pat. No. 4,729,970 describes that the conversion process for passivating short circuit paths in semiconductor devices may be activated by selectively illuminating shunted areas to activate the conversion reaction in those areas. The present invention does not rely upon illumination for activating the reaction, and also does not require selective illumination or knowledge of the locations of shunted areas.

Referring first to the prior art, FIG. 1 is a schematic illustration of the prior art structure of a defect-free thin-film amorphous silicon/germanium (a-Si/a-SiGe/a-SiGe) triple junction solar cell made by glow discharge. There is no direct electrical path between the stainless steel/back reflector layer and the top transparent conducting electrode.

FIG. 2 is also a schematic illustration of the prior art structure of a shunted thin-film amorphous silicon/germanium (a-Si/a-SiGe) triple junction solar cell made by glow discharge chemical vapor deposition. The shunt provides a direct electrical path between the stainless steel/back reflector layer and the top transparent conducting electrode, thus causing the solar cell to be short-circuited; i.e., the current that is meant to flow through the external circuit is diverted through the shunt. This leads to a severe reduction in yield and performance of the solar cells.

The present invention improves upon the process described in U.S. Pat. No. 4,729,970, and provides increased yield and performance of the solar cells.

### SUMMARY OF THE INVENTION

The present invention provides an improved method of eliminating or reducing the effects of short circuit (shunt) defects in a-Si photovoltaic devices, or other photovoltaic devices having a transparent conducting oxide (TCO) as the top layer.

In one aspect, the present invention relates to a method of passivating any performance-reducing shunting defects in a photovoltaic cell having one or more layers of a thin film semiconductor material and layer of a superposed electrode. The method includes immersing at least a portion of the photovoltaic cell in a conversion reagent, illuminating at least a portion of the immersed photovoltaic cell with a suitable source of illumination, and applying an appropriate electrical bias on the immersed photovoltaic cell.

In certain embodiments, the method includes using an electrolyte which increases the resistivity of the electrode near the performance reducing shunt when an electrical bias is applied in a preferred range, while any change in resistivity is substantially smaller outside of the bias range. Further, in certain embodiments, the method includes illuminating the photovoltaic cell with a wavelength which activates the thin film semiconductor layer and causes production of a photovoltage. The photovoltaic cell is illuminated with a suitable wavelength or wavelengths and a sufficient intensity such that the photovoltage produced by the illumination in an unshunted region inhibits the increase of the resistivity of the electrode material in the unshunted regions.

In certain embodiments, the electrode is a transparent and an electrically conductive material which is superposed on an illumination side of the semiconducting layer. Further, in certain embodiments, the electrode is on a backside of the semiconductor layers, opposite to an illumination-entering side. Also, the semiconductor layers are illuminated from the illumination-entering side during the passivation process. The solar cell is partially or fully illuminated without restricting the illumination to only the shunted regions or near the shunted regions.

In another aspect, the present invention relates to an apparatus for performing the light-assisted shunt passivation which includes an electrolyte, a counter-electrode, a conducting electrode placed in near or in contact with an opposing electrode of the photovoltaic cell. In certain embodiments, the apparatus further includes a source of illumination positioned in opposing relationship to the conducting electrode. The illumination source can be comprised of wavelengths which activate the thin film semiconductor layers.

In other aspects, the present invention also relates to photovoltaic devices made using the method and/or apparatus described herein.

The passivation reaction is much more selective when the cell is illuminated, because the unshunted portions of the cell produce a voltage that actively opposes the one required for the passivation to take place. This increases the acceptable range of the electrical bias for effective shunt passivation and the process passivates shunts with different levels of severity without causing unwanted conversion of the transparent conducting electrode (TCE) into a more electrically resistive material in the unshunted areas.

In certain embodiments, the passivation can be carried out in two or more steps, so that shunt levels with different levels of shunting resistance could be more effectively passivated. The first step of the two-step passivation is done with a relatively smaller voltage, under appropriate illumination. This increases the electrode resistance in all shunted areas, including the small shunts and big shunts. However, when the bias voltage applied is small the increase in resistance may not be sufficient for shunts of a certain severity. If necessary, a second passivation may then be performed, also under illumination, with a greater bias voltage. This would lead to a larger increase in TCE resistance around residual shunts. Since the TCE around the shunts already passivated has already become more resistive and also the sample is under illumination, the second passivation would not lead to the increase of TCE resistance in unnecessarily large area, thus preventing a reduction in the short circuit current and the solar cell fill factor. Instead of applying the bias voltage in steps, a voltage ramp may also be employed wherein the bias voltage is changed smoothly during the period of shunt passivation.

Therefore, a broad range of possible shunts can be effectively passivated using the method of the present invention.

Other objects and advantages of the present invention will become apparent to those skilled in the art upon a review of the following detailed description of the preferred embodiments and the accompanying drawings.

### BRIEF DESCRIPTION OF THE DRAWINGS

The patent or application file contains at least one drawing executed in color. Copies of this patent or patent application publication with color drawings(s) will be provided by the United States Patent and Trademark Office upon request and payment of the necessary fee.

FIG. 1 is a schematic illustration of the prior art structure of a defect-free thin-film amorphous silicon/germanium (a-Si/a-SiGe/a-SiGe) triple junction solar cell made by glow discharge chemical vapor deposition.

FIG. 2 is a schematic illustration of the prior art structure of a shunted thin-film amorphous silicon/germanium (a-Si/a-SiGe/a-SiGe) triple junction solar cell made by glow discharge chemical vapor deposition.

FIG. 3 is a schematic illustration of a suitable apparatus useful to perform the light-assisted shunt passivation.

FIG. 4 is a schematic illustration of the structure of a shunted thin-film amorphous silicon/germanium (a-Si/a-SiGe/a-SiGe) triple junction solar cell that has been subjected to the shunt passivation method described herein.

FIG. 5a is a graph showing the current-voltage characteristics of a shunted a-Si triple junction solar cell, before shunt passivation, for a first device, GD1065-1.

FIG. 5b is a graph showing the current-voltage characteristics of the same solar cell, after shunt passivation, for a first device, GD1065-1.

FIG. 5c is a graph showing the current-voltage characteristics of a shunted a-Si triple junction solar cell, before shunt passivation, for a second device, GD1065-3.

FIG. 5d is a graph showing the current-voltage characteristics of the same solar cell, after shunt passivation, for a second device, GD1065-3

FIGS. 6a, 6b, 6c and 6d are graphs showing a comparison of the results produced by the method of the present invention (“light”) with those produced by the Nath process (U.S. Pat. No. 4,729,970) (“dark”) on a set of amorphous silicon solar cells.

FIG. 7 is a graph showing the effect of electrolyte concentration on effectiveness of the shunt passivation process.

FIG. 8 is a graph showing the effect of applied bias voltage on effectiveness of the shunt passivation process.

FIG. 9 is a graph showing the effect of passivation time on the effectiveness of the shunt passivation process.

FIG. 10 is a graph showing the effect of bias light intensity on the effectiveness of the shunt passivation process.

FIG. 11a is a graph showing the effect of illumination during passivation on relative quantum efficiency.

FIG. 11b is a micrograph of solar cell passivated at 1.4V for 5 seconds, in dark. 1.4 V was the minimum bias voltage required for passivation in dark.

FIG. 11c is a micrograph of solar cell passivated at 3V for 5 seconds, illuminated with 100 mW/cm².

FIG. 11d is a photograph of solar cells passivated at 2V for 5 seconds, illuminated (bottom) and unilluminated (top).

FIG. 12 is a schematic illustration of a suitable apparatus useful to perform another embodiment of the light-assisted shunt passivation method.

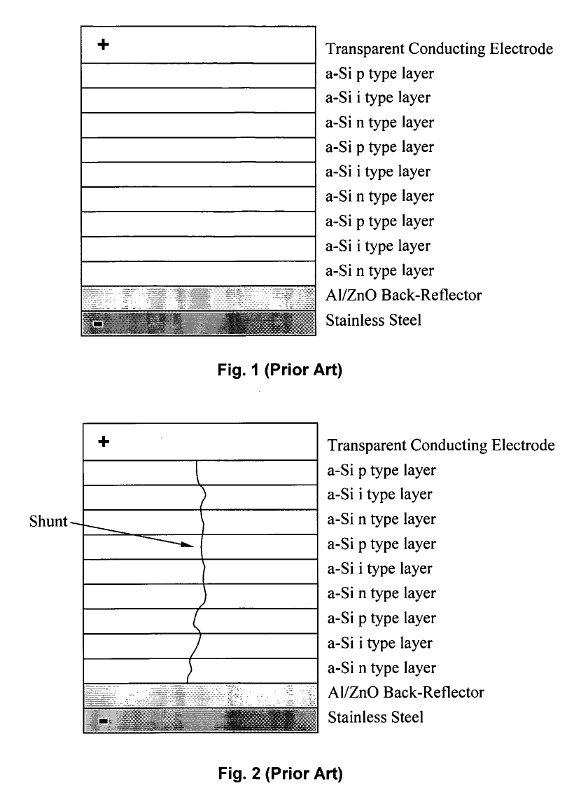

### DETAILED DESCRIPTION OF THE PREFERRED EMBODIMENT(S)

The present invention relates to a method and apparatus for passivating short circuit defects in a photovoltaic device. Generally, the photovoltaic device includes a thin film body with a superposed electrode comprised of a layer of transparent electrically conductive material.

The present invention uses 1) an external electric bias to impress the current required for the passivation reaction to occur, and 2) uses simultaneous illumination of the solar cell, whereby the natural photovoltage thus produced prevents the solar cell from being forward biased. The present method can successfully be applied to single, double and triple junction a-Si solar cells. Substantial shunt passivation may be attained in as little as one second, while unwanted conversion of ITO is suppressed.

According to the one aspect of the present invention, the electrode is immersed in a conversion reagent which is adapted to convert the transparent, electrically conductive electrode material to a material of a higher electrical resistivity. The method further includes simultaneously illuminating the immersed electrode with light and applying an electrical bias on the device. In preferred embodiments, the light is comprised of such wavelengths as would activate the thin film semiconductor layers underneath the transparent electrode leading to the production of a photovoltage. Through proper choice of the electrolyte, electrical bias and illumination, the transparent conductor is converted to an insulator in the regions near the performance reducing shunts, while the transparent conductor, in the unshunted regions, remains unchanged. In this manner, the defect regions alone are substantially electrically isolated from the remainder of the electrode.

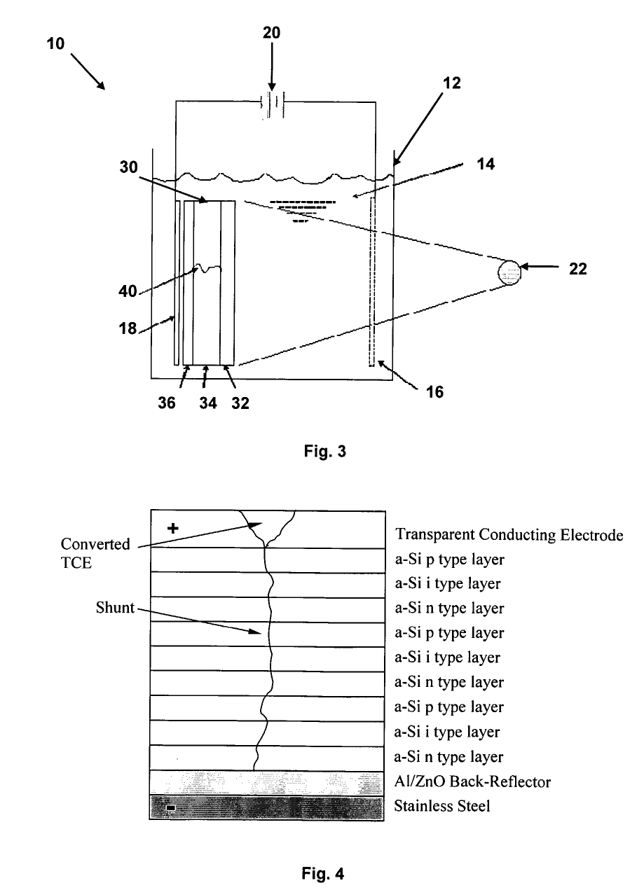

Referring now to FIG. 3, a schematic illustration of a suitable apparatus 10 useful to perform the light-assisted shunt passivation method of the present invention is generally shown. A container 12 holds a suitable quantity of a suitable conversion reagent 14. In the embodiment shown, the suitable conversion reagent 14 comprises an electrolyte such as aqueous solution of aluminum chloride (AlCl₃) of conductivity 40 mS. A counter-electrode 16 is positioned within the electrolyte 14 and is operatively connected to one terminal of a voltage supply 20. In the embodiment shown, the counter-electrode is light transmissive, such as an aluminum mesh that allows the passage of light.

A second electrode 18 is positioned within the electrolyte 14 and is operatively connected to a second terminal of the voltage supply 20. In the embodiment shown, the second electrode 18 comprises a steel electrode.

The apparatus 10 further includes a suitable source of illumination 22 which is positioned in opposing relationship to the first, light transmissive electrode 16. In certain embodiments, the illumination source 22 is comprised of wavelengths which activate the thin film semiconductor layers underneath the transparent electrode leading to the production of a photovoltage. In certain embodiments, the illumination source 22 can comprise a tungsten halogen lamp.

A photovoltaic device 30 is positioned within the electrolyte 14 adjacent to second electrode 18. In the embodiment shown the photovoltaic device 30 generally includes a layer of transparent electrically conductive (TCE) electrode material 32, a solar cell material 34, and a back electrode 36. It is to be understood that it is within the contemplated scope of the present invention that the solar cell material 34 can be a single, a double or a triple junction cell (either of the nip type or pin type). In the embodiment shown in FIG. 3, a shunt 40 is schematically illustrated.

The second electrode 18 is placed in near, or in contact with, the back electrode 36 of the photovoltaic device 30.

According to one aspect of the present invention, the shunt passivation process is as follows: First, a front surface of the transparent electrically conductive (TCE) electrode material 32 of the photovoltaic device 30 is illuminated by the illumination source 22. Second, an electrical bias of approximately 2 volts is applied between the electrode 16 and the second electrode 18 for a period of the order of from about 1 to about 5 seconds. Third, at the end of this period, the power supply is disconnected. Finally, the photovoltaic device 30 removed, rinsed with water and dried and the illumination source 22 is switched off.

The activation of shunt passivation process may be different for different types of devices. For example, the optimal value and the polarity of the applied electrical bias will depend on the polarity of the photovoltaic devices (whether it is nip type or pin type), the type of transparent conducting electrode, and the electrolyte solution to be used. For example, the passivation of a triple-junction a-Si based solar cell 34, as shown in the apparatus shown in FIG. 3, is used to illustrate the process. The cell 34 is an amorphous silicon nip/nip/nip triple junction cell deposited on a stainless steel substrate 36, such that the n layer of the bottom cell is nearest the steel substrate 36 and the transparent conducting electrode 32 (indium tin oxide, ITO) is deposited on the p layer of the top cell.

It may be noted that when a minimum voltage of approximately −1 volt is present at the interface of this transparent conducting electrode (TCE), the passivation reaction proceeds; i.e., the TCE needs to be approximately 1 volt negative with respect to the electrolyte. This reaction does not proceed if the TCE is positive with regard to the electrolyte.

Due to the illumination, the unshunted areas of the cell produce a photovoltage, the magnitude of which, in this case, is 2.2 V; i.e., the transparent conducting electrode near unshunted areas of the cell will be 2.2 volts positive with respect to the stainless steel back electrode. The shunted areas, however, do not produce this photovoltage; or if they do, it is of a much smaller magnitude than 2.2 volts.

To perform shunt passivation, a positive electrical bias of approximately 2 volts is applied to the counter electrode 16 (aluminum mesh through light penetrates), i.e., the stainless steel back contact 36 of the cell is held negative with respect to the counter electrode 16 by 2 volts. It may be noted that the polarity of the photovoltage produced by the unshunted portions of the cell is such as to oppose the electrical bias. For this reason, the voltage present at the TCE 32 in those portions will be small, zero, or even positive with respect to the electrolyte 14. Hence, there is no reaction in those portions of the TCE 32, or it is very slow. On the other hand, the shunted portions of the cell produce smaller or no photovoltage. As a result, a large portion (greater than 1 V) of the applied electrical bias voltage (2 V) appears across the TCE/electrolyte interface, and it will be noted that the polarity is such that the TCE becomes negative with respect to the electrolyte. Thus, the passivation reaction proceeds at a high rate in the shunted regions.

In the absence of illumination (such as described in the process of Nath et al.), even the unshunted portions of the cell are under a forward bias, there being no photovoltage to oppose the electrical bias. This leads to a small but possibly significant current flow in these regions, due to the applied bias voltage. This current may be large enough to make the TCE sufficiently negative with respect to the electrolyte, and therefore, the passivation reaction may occur even in the unshunted regions. The effectiveness of shunt passivation process without simultaneous illumination is limited since there is a relatively narrow window for the applied bias voltage and the optimal voltage may be different when the shunts have different shunt resistance. For example, if the electrical bias voltage is too large, the unshunted area would be under sufficient high forward bias and the undesirable increase of TCE resistivity occurs. On the other hand, when the voltage bias is too small, there may not be sufficient voltage at the shunted area to activate the shunt passivation. Therefore, only some selected numbers of shunts with a defined level of severity could be passivated. When the shunt resistance is too large or too small as compared to the optimal shunting resistance for un-illuminated passivation, the shunts are not effectively passivated. This limits the scope and effectiveness of the passivation process since one cannot control or predetermine the size of the shunts.

It is clear from the preceding that the passivation reaction is much more selective when the cell is illuminated, because the unshunted portions of the cell produce a voltage that actively opposes the one required for the passivation to take place. This increases the acceptable range of the electrical bias for effective shunt passivation and the process passivate shunts with different levels of severity without causing unwanted conversion of TCE into a more electrically resistive material in the unshunted areas.

Therefore, a broad range of possible shunts can be effectively passivated using the method of the present invention.

In the process described by prior art (U.S. Pat. No. 4,729,970 to Nath et al.), a method of passivation using illumination in the defective area is also discussed. However, this earlier process requires that the shunted area be pre-defined and positions located since the laser illumination, as described, needs to be directed at the shunted area. Since the positions of shunts are usually unknown before the passivation, the application of such an earlier process is limited. In contrast, in the present invention, the entire solar cell is illuminated. The illumination is not restricted to shunted areas and light is not used to activate the passivation reaction that converts the transparent conducting electrode to an insulator. The light is used herein to generate a photovoltage in the unshunted area so that undesirable conversion of TCE in these unshunted areas could be prevented.

FIG. 4 is a schematic illustration of the structure of a shunted thin-film amorphous silicon/germanium (a-Si/a-SiGe/a-SiGe) triple junction solar cell that has been subjected to the shunt passivation process described herein. The transparent, electrically conducting material in the regions near the shunt is converted to a high resistivity material, thereby electrically isolating the shunt from the rest of the solar cell. Testing shows that the process described herein successfully restores the performance of shunted amorphous silicon solar cells. The method of the present invention passivates shunts created during manufacture (due to dust, etc.) as well as those due to mishandling (scratches, etc) after manufacture.

In certain embodiments, the thin film semiconductor layers are suitably doped and undoped amorphous or microcrystalline silicon, amorphous or microcrystalline germanium or their alloys.

Also, in certain embodiments, the transparent, electrically conducting material can comprise indium-tin oxide (ITO), indium oxide (In₂O₃), tin oxide (SnO₂), or other related materials.

Also, in certain embodiments, the electrolyte could be an aqueous solution of aluminum chloride (AlCl₃), dilute sulfuric acid H₂SO₄) dilute copper sulfate (CuSO₄), or a weak solution of ammonium hydroxide (NH₄OH).

Various types of light sources are useful in the present invention. For example, the source of illumination can be a tungsten halogen lamp. It is to be noted that the entire surface of the electrode can be illuminated, i.e., the illumination need not be restricted to shunted regions. The activation of the electrolyte, and the subsequent passivation reaction, is not due to the illumination. Rather, according to one aspect of the present invention, the source of illumination is preferably chosen to have suitable wavelength and sufficient intensity such that the photovoltage produced by the illumination in the unshunted region inhibits the increase of the resistivity of the electrode material in those regions.

The foregoing has outlined in broad terms the more important features of the invention disclosed herein so that the detailed description that follows may be more clearly understood, and so that the contribution of the instant inventor to the art may be better appreciated. The instant invention is not to be limited in its appreciation to the details of the construction and to the arrangements of the components set forth in the description herein or illustrated in the drawings herein. Rather, the invention is capable of other embodiments and of being practiced and carried out in various other ways not specifically enumerated herein.

In one aspect, the light assisted electrochemical shunt passivation process may also be applied to cells of a superstrate configuration made on glass. The resistivity of the back electrode, rather than that of the front electrode, is increased substantially in regions surrounding current-shunting defects, while unwanted increases in resistivity in unshunted regions during shunt passivation are inhibited by illuminating the semiconductor layers from the sunlight-entry (glass) side.

Finally, it should be understood that the phraseology and terminology employed herein are for the purpose of description and should not be regarded as limiting, unless the specification specifically so limits the invention.

### EXAMPLE I

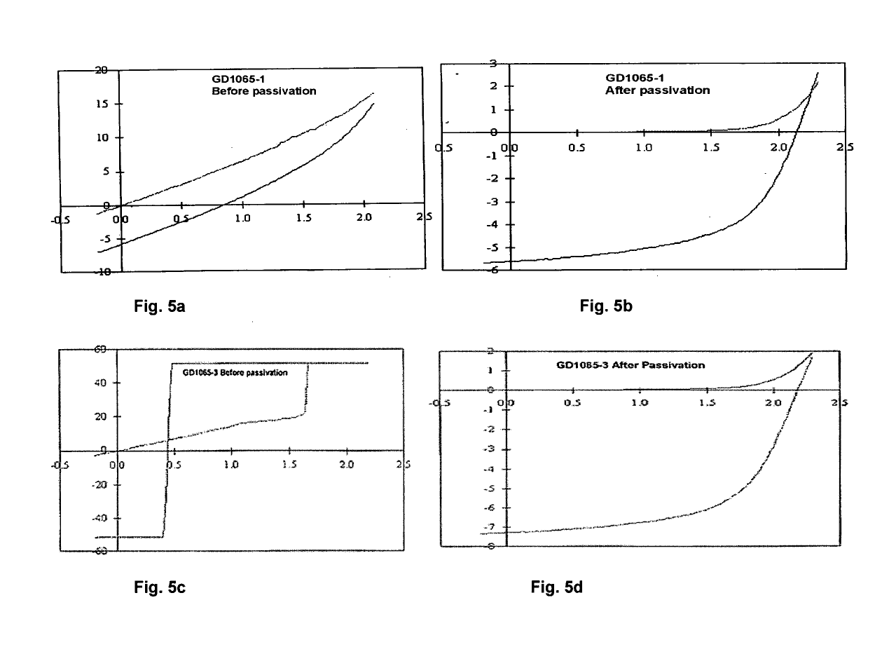

FIG. 5a is a graph showing the current-voltage characteristics of a shunted a-Si triple junction solar cell, before shunt passivation, for a first material, GD1065-1.

FIG. 5b is a graph showing the current-voltage characteristics of the same solar cell, after shunt passivation, for a first material, GD1065-1.

FIGS. 5(a) and 5(b) show one example of the shunt passivation performed by the method described herein on an amorphous silicon triple junction solar cell.

FIG. 5(a) shows the dark and illuminated current-voltage characteristics of the cell before shunt passivation. The curves indicate that the cell has a low shunt resistance, and consequently a low room light open circuit voltage, low fill factor and low efficiency. Such a cell is generally considered “dead”.

FIG. 5(b) shows the current-voltage characteristics of the same cell after shunt passivation. The fill factor increased from 26% to 56% and the efficiency from 1.3% to 6.7%. Open circuit voltage increased from 0.85 V to 2.14 V. The shunt resistance increased from 160 ohm-cm² to 3238 ohm-cm². Thus, the fill factor, efficiency and open circuit voltages all improved to a normal level and the shunt resistance increases significantly, indicating isolation of the shunt(s).

### EXAMPLE II

FIG. 5c is a graph showing the current-voltage characteristics of a shunted a-Si triple junction solar cell, before shunt passivation, for a second material, GD1065-3.

FIG. 5d is a graph showing the current-voltage characteristics of the same solar cell, after shunt passivation, for a second material, GD1065-3.

FIGS. 5(c) and 5(d) show the current-voltage curves for another triple junction amorphous silicon cell before and after shunt passivation. FIG. 5(c) shows the current-voltage characteristics of a severely shunted triple junction solar cell. FIG. 5(d) shows the current voltage characteristics of the same cell after shunt passivation. All cell parameters recovered to normal values.

For both these examples the method of the present invention was used for shunt passivation. A 2 volt, 5 second pulse was applied to the solar cell. Aqueous AlCl₃ was used as an electrolyte and illumination was from a tungsten halogen lamp.

### EXAMPLE III

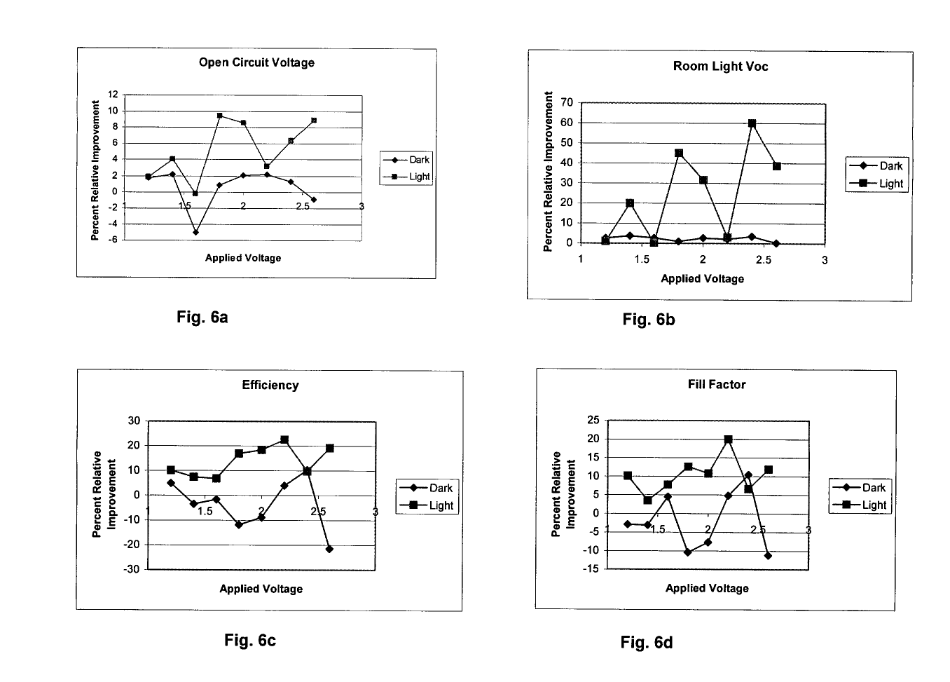

FIGS. 6a, 6b, 6c and 6d are graphs showing a comparison of the results produced by the method of the present invention (“light”) with those produced by the Nath et al. process (U.S. Pat. No. 4,729,970) (“dark”) on a set of amorphous silicon solar cells. Each point on the graphs is an average of data from three separate samples. The graphs show the relative improvement in the open circuit voltage under AM1 (FIG. 6a), under 5% illumination (“room light”) (FIG. 6b), efficiency (FIG. 6c), and fill factor (FIG. 6d) for both processes, and at different applied electrical biases. The graphs show that there is at least one electrical bias at which the process described here outperforms the prior art process of Nath et al.

FIGS. 6 (a) through (d) indicate that by using the Nath et al. process (“Dark”), some samples show good improvement, but some samples actually deteriorate relative to their state before shunt passivation. With the process described in the present invention (“Light”), all samples either show improvement, or are unchanged from their state before passivation. The applicants of this patent application attribute this improvement to the superior selectivity of the passivation process when accompanied by illumination, as described above.

### EXAMPLE IV

In another embodiment, instead of converting the transparent, electrically conductive electrode material to a material having a higher electrical resistivity than the transparent electrically conductive electrode material, it is within the contemplated scope of the present invention to instead remove the transparent conducting electrode material form the photovoltaic device. That is, instead of being converted to a high resistivity material, the transparent conducting electrode may be removed altogether.

### EXAMPLES V-1-V-5

In the following examples, the samples used were triple-junction amorphous silicon solar cells with the following structure: Steel/n/i/p/n/i/p/n/i/p/ITO. The samples in the examples were artificially shunted with laser pulses of controlled energy, in order to generate shunts of relatively consistent nature, in order to enable proper comparison of the parameters and methods. However, it should be understood that these experiments have also been performed on solar cells with shunts created by scratches or handling and also on cells with shunts created naturally during manufacture, with similar results. These samples were expected to produce an open circuit voltage of 2.15 V under 1-sun illumination, if no shunting is present. Under light, a positive voltage relative to the stainless steel substrate is applied onto the ITO film by the solar cells in unshunted areas. The open circuit voltages of the samples were measured before and after shunt passivation under solar simulator light of 2.5% of 1-sun and 20% of 1-sun intensities. The open circuit voltage of a solar cell under such reduced light is known to be a good indicator of the extent of shunting present in the cell. Open circuit voltage measured under weaker light intensity (2.5%) reveals less severe shunts compared to that measured under stronger illumination, and is therefore a stronger criterion for comparison. The higher the open circuit voltage, the lower the extent of shunting, i.e. the more complete the shunt passivation process. Aluminum chloride solution was used as the electrolyte. Electrolyte temperature was 21-23 C in all cases.

### EXAMPLE V-1

### Effect of Electrolyte Concentration on Effectiveness of the Shunt Passivation Process

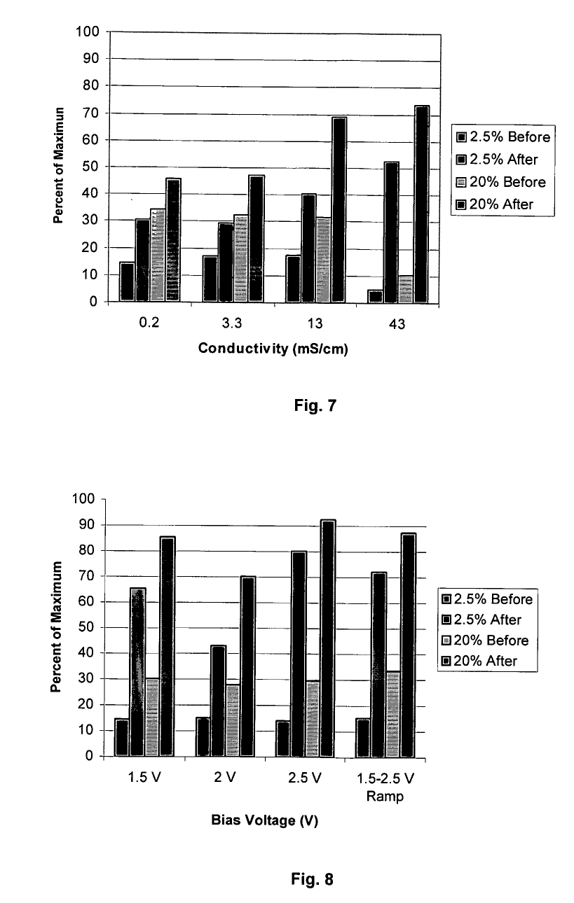

Shunt passivation was carried out using aluminum chloride solution of four different conductivities (0.2, 3.3, 13, 43 mS/cm), corresponding to four different concentrations. A voltage bias of 2 volts was applied for 10 seconds in each case, with the mesh counter electrode positive with respect to the sample. The samples were illuminated at all times with light from a tungsten-halogen lamp, with an intensity of 100 mW/cm². Fifteen samples were passivated at each concentration. FIG. 7 shows the results of the experiment. The mean voltage relative to the maximum of 2.15V is plotted for each concentration. It may be concluded that higher electrolyte conductivities lead to more complete passivation, while other factors remain the same.

FIG. 7 shows the effect of electrolyte concentration on effectiveness of the shunt passivation process. The average open circuit voltage relative to the voltage of unshunted cells, was measured at two light intensities (2.5% or 20% of 1 sun intensity) before and after electrochemical shunt passivation at different electrolyte concentrations (conductivities). The higher the open circuit voltage, the lower the extent of shunting. The open circuit voltage under weak light (2.5%) is a better indicator of the extent of shunting than that under the stronger light (20%).

### EXAMPLE V-2

### Effect of Applied Bias Voltage on Effectiveness of the Shunt Passivation Process

Shunt passivation was carried out using aluminum chloride solution of 43 mS/cm conductivity. Four different voltage biases were tested: steady voltages of 1.5, 2.0 and 2.5V, and a ramped voltage of 1.5-2.5 V. Voltage bias was applied for 10 seconds in all cases, with the mesh counter electrode positive with respect to the sample. The samples were illuminated at all times with light from a tungsten-halogen lamp, with an intensity of 100 mW/cm². Fifteen samples were passivated at each bias condition. FIG. 8 shows the results of the experiment. The mean open circuit voltage relative to the maximum of 2.15V is plotted for each voltage bias condition. The bias voltage of 2.5V was found to produce the most complete passivation in this case. However, light assisted shunt passivation was found to have a broad range of acceptable bias voltages. Voltages up to 3V have been tested and found to perform well, while unwanted conversion of ITO is suppressed (see example V5).

FIG. 8 shows the effect of applied bias voltage on effectiveness of the shunt passivation process. The average open circuit voltage relative to the voltage of unshunted cells, was measured at two light intensities (2.5% or 20% of 1 sun intensity) before and after electrochemical shunt passivation at different bias voltages (1.5, 2, 2.5V and a ramp of 1.5-2.5V). The higher the open circuit voltage, the lower the extent of shunting. The open circuit voltage under weak light (2.5%) is a better indicator of the extent of shunting than that under the stronger light (20%).

### EXAMPLE V-3

### Effect of Passivation Time on the Effectiveness of the Shunt Passivation Process

Shunt passivation was carried out using aluminum chloride solution of 43 mS/cm conductivity. Sets of 15 samples each were passivated for 1, 5, 10 and 30 seconds. Voltage bias was 2V in all cases, with the mesh counter electrode positive with respect to the sample. The samples were illuminated at all times with light from a tungsten-halogen lamp, with an intensity of 100 mW/cm².

FIG. 9 shows the results of the experiment. The mean open circuit voltage relative to the maximum of 2.15V is plotted for each voltage bias condition. Shunt passivation can be achieved in 30 seconds or less, and possibly in as little as one second, i.e. light assisted shunt passivation has a broad window for passivation time (1-30 s).

FIG. 9 shows the effect of passivation time on the effectiveness of the shunt passivation process. The average open circuit voltage relative to the voltage of unshunted cells, was measured at two light intensities (2.5% or 20% of 1 sun intensity) before and after electrochemical shunt passivation carried out for different periods of time (1, 5, 10 and 30 seconds). The higher the open circuit voltage, the lower the extent of shunting. The open circuit voltage under weak light (2.5%) is a better indicator of the extent of shunting than that under the stronger light (20%).

### EXAMPLE V-4

### Effect of Bias Light Intensity on the Effectiveness of the Shunt Passivation Process

Shunt passivation was carried out using aluminum chloride solution of 43 mS/cm conductivity. Two sets of 15 samples each were passivated at 100 mW/cm² and 10 mW/cm² illumination for 10 seconds with a voltage bias of 2V, with the mesh counter electrode positive with respect to the sample. The samples were illuminated at all times.

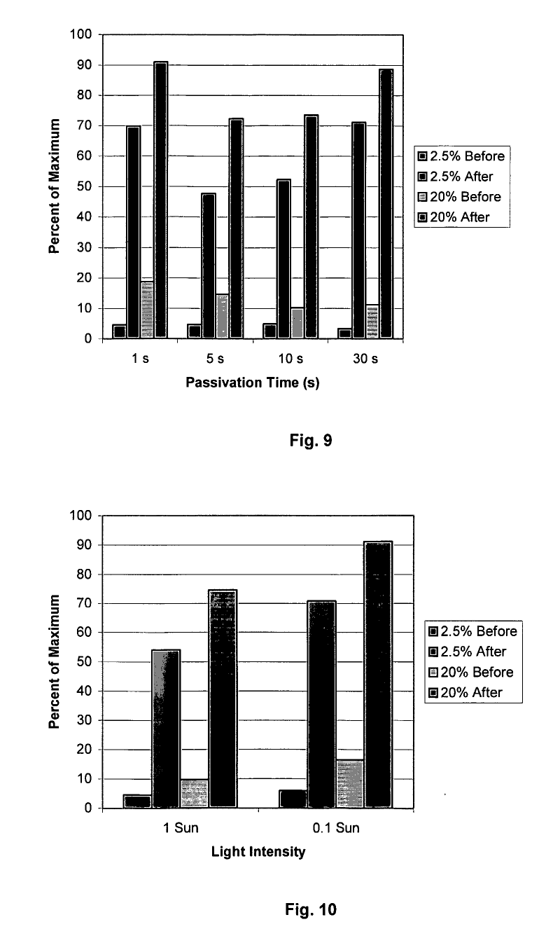

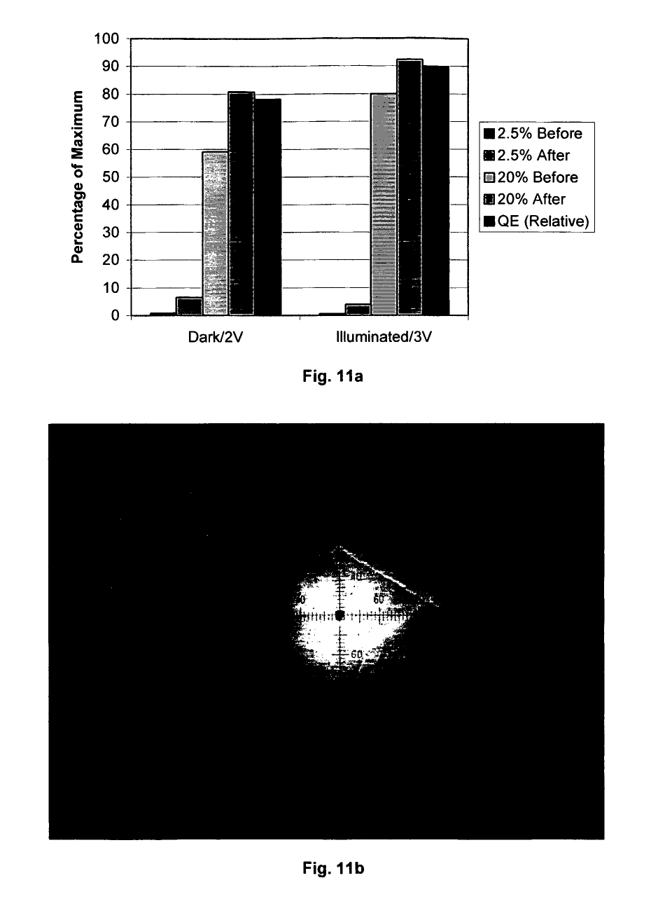

FIG. 10 shows the results of the experiment. The mean open circuit voltage relative to the maximum of 2.15V is plotted for each light intensity condition. In this example, the passivation is more complete at the lower intensity, possibly indicating that the photovoltage produced by the cell being passivated reduces the bias voltage in the regions surrounding the shunt to the extent that it is insufficient to produce full passivation in 10 seconds, i.e. a longer passivation time may be required. However, as shown in examples 2 and 5, a bias of 2.5V or 3V is sufficient when applied for 10 s, with 1 sun illumination. The light bias did guard against unwanted conversion of the ITO, as in all other examples. This is further described by referring to Example V-5.

FIG. 10 shows the effect of bias light intensity on the effectiveness of the shunt passivation process. The average open circuit voltage relative to the voltage of unshunted cells, was measured at two light intensities (2.5% or 20% of 1 sun intensity) before and after electrochemical shunt passivation carried out at two different intensities of illumination (10 and 100 mW/cm²). The higher the open circuit voltage, the lower the extent of shunting. The open circuit voltage under weak light (2.5%) is a better indicator of the extent of shunting than that under the stronger light (20%).

### EXAMPLE V-5

### Effect of Bias Light on Unwanted Conversion of the ITO Top Contact

Shunt passivation was carried out using aluminum chloride solution of 43 mS/cm conductivity. Two sets of 8 samples each were passivated at 100 mW/cm² and ˜1 mW/cm² (dark) illumination for 10 seconds with a voltage bias of 3V and 2V respectively, with the mesh counter electrode positive with respect to the sample. The voltage biases were chosen to operate the processes near their respective optimal points. The samples were illuminated with the corresponding light intensities at all times.

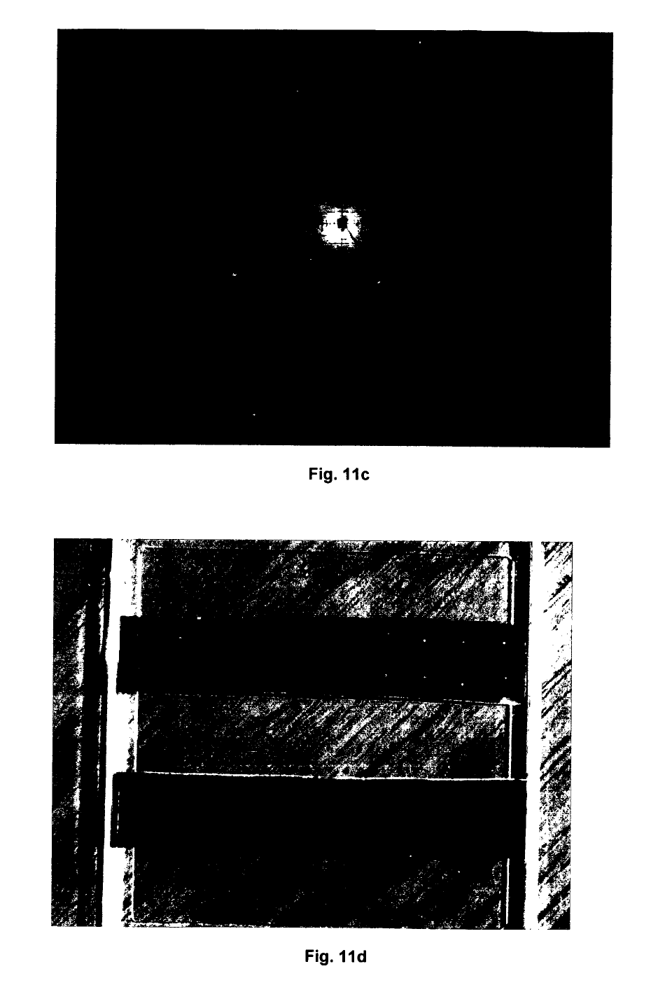

FIG. 11a shows the results of the experiment. The quantum efficiencies measured at 450 nm in the region surrounding the shunted spot were measured. The mean quantum efficiencies in arbitrary units are plotted for each light intensity condition, along with the open circuit voltages. The photographs in FIGS. 11b and 11c show micrographs of samples passivated in the dark (11b) and in light of intensity 1 sun (11c). The photographs are to the same scale. The samples initially had similar degrees of shunting, as reflected by the open circuit voltages. This experiment was also repeated with bias voltages of 2V for both the dark and illuminated sets. The results were similar, as shown in FIG. 11d.

FIG. 11a shows the effect of illumination during passivation on relative quantum efficiency.

FIG. 11b is a micrograph of solar cell passivated at 1.4V for 5 seconds, in dark (˜1 mW/cm²). 1.4 V was the minimum bias voltage required for passivation in dark in this particular case. Open circuit voltage recovered from 0.007V/0.049V to 1.750/1.995V (at 2.5%/20% intensity), indicating complete shunt passivation. The passivation has affected a large area of roughly 1.44 mm². The affected area shows reduced efficiency. In general, a bias of at least 2V was required for complete passivation without light bias. At 2V, the affected area is even larger.

FIG. 11c is a micrograph of solar cell passivated at 3V for 5 seconds, illuminated with 100 mW/cm². Open circuit voltage recovered from 0.007V/0.043V to 1.742/1.993V (at 2.5%/20% intensity), indicating complete shunt passivation. The passivation has affected an area of roughly 0.16 mm², 9 times less than in the unilluminated case.

FIG. 1d is a photograph of solar cells passivated at 2V for 5 seconds, illuminated (bottom) and unilluminated (top). The samples initially had similar degrees of shunting, as reflected by the open circuit voltages.

### EXAMPLE VI

Application of the Light Assisted Shunt Passivation Process to a Cadmium Sulfide/Cadmium Telluride Superstrate Type Solar Cell.

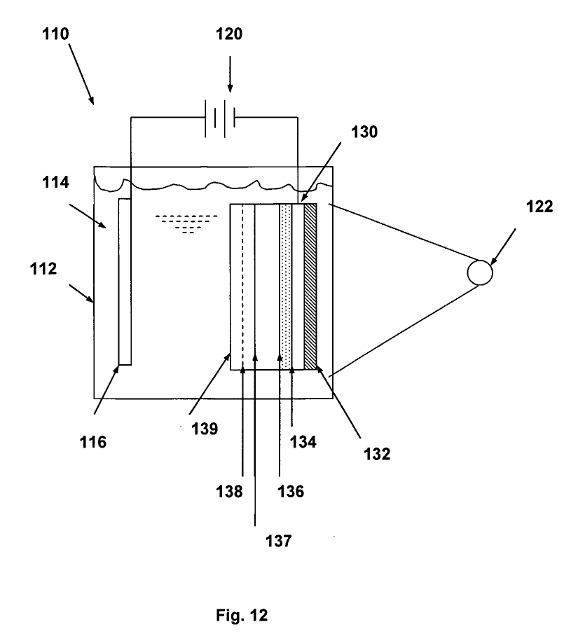

Referring now to FIG. 12, a schematic illustration of a suitable apparatus 110 useful to perform another embodiment of the light-assisted shunt passivation method of the present invention is generally shown. A container 112 holds a suitable quantity of a suitable conversion reagent 114. In the embodiment shown, the suitable conversion reagent 114 comprises an electrolyte such as aqueous solution of aluminum chloride (AlCl₃) of conductivity 40 mS. A counter-electrode 116 is positioned within the electrolyte 114 and is operatively connected to one terminal of a voltage supply 120. In the embodiment shown, the counter-electrode 116 can be a solid plate such as aluminum. A photovoltaic device 130, which acts as a second electrode, is positioned within the electrolyte 114 and is operatively connected to a second terminal of the voltage supply 120.

In certain embodiments, the apparatus 110 can further include a suitable source of illumination 122 which is positioned in opposing relationship to the solar cell 130.

In certain embodiments, the illumination source 122 is comprised of wavelengths which activate the thin film semiconductor layers underneath the transparent electrode leading to the production of a photovoltage. In certain embodiments, the illumination source 122 can comprise a tungsten halogen lamp.

In the embodiment shown, the photovoltaic device 130 generally includes a layer of glass 132 having a coating 134 such as a tin oxide, including, for example SnO₂:F. A layer 136 of CdS is sputtered onto the coated glass 132/134. A layer 137 of CdTe is coated onto the CdS layer 137. In certain embodiments, a buffer layer 138 is added, and is shown in the FIG. 12; however, it should be understood that, in other embodiments, the buffer layer 138 can be omitted. A thin intermediate layer 139 of indium-tin oxide (ITO) may then be sputtered onto the CdTe layer 137, or onto the buffer layer 138.

The cell is then immersed in the electrolyte 114 and illuminated from the glass side 132 of the photovoltaic cell 130. In this embodiment, a suitable electrical bias, where the counter electrode 118 is positive and the tin oxide front contact of the photovoltaic cell 130 is negative, is applied for a few seconds, to increase the resistivity of the ITO in the shunted regions.

According to one aspect of the present invention, the shunt passivation process is as follows: First, a front surface of the photovoltaic device 130 is illuminated by the illumination source 122. Second, an electrical bias of approximately 2 volts is applied between the electrode 116 and the photovoltaic cell 130 for a period of the order of from about 1 to about 30 seconds, and in some embodiment 1 to about 5 seconds. Third, at the end of this period, the power supply is disconnected. Finally, the photovoltaic device 130 is removed, rinsed with water and dried, and the illumination source 122 is switched off

Although the cell would be forward biased if it were unilluminated, the natural photovoltage produced by the solar cell when illuminated is of the correct polarity to cancel or reduce the forward bias, inhibiting unwanted increase in resistance of ITO in unshunted regions. After passivation, the ITO may be covered with a layer of metal to form the final back contact. Thus, the shunted regions of the cells are isolated from the conductive metal back contact by the resistive portions of ITO.

### EXAMPLE VII

In certain embodiments, the passivation is carried out in two or more steps, so that shunt levels with different shunting resistance is more effectively passivated. The first step of the two-step passivation is done with a relatively small voltage. This increases the electrode resistance in all shunted areas, including the small shunts and big shunts. However, when the bias voltage applied is small, the increase in resistance may not be sufficient for shunts or a certain severity. If necessary, a second passivation may then be performed, also under illumination, with a greater bias voltage. This two-step passivation leads to a larger increase in TCE resistance around residual shunts. Since the TCE around the shunts already passivated has already become more resistive and since the sample is under illumination, the second passivation would not lead to the increase of TCE resistance in an unnecessarily large area, thus preventing a reduction in the short circuit current and the solar cell fill factor.

In another embodiment, instead of applying the bias voltage in steps, a voltage ramp may also be employed wherein the bias voltage is changed substantially smoothly during the period of shunt passivation.

The above detailed description of the present invention is given for explanatory purposes. It will be apparent to those skilled in the art that numerous changes and modifications can be made without departing from the scope of the invention. For example, instead of being converted to a high resistivity material, the transparent conducting electrode may be removed altogether. Accordingly, the whole of the foregoing description is to be construed in an illustrative and not a limitative sense, the scope of the invention being defined solely by the appended claims.

We claim:

1. A method of passivating any performance-reducing shunting defects in a photovoltaic cell having one or more layers of a thin film semiconductor material and layer of a superposed electrode, the method comprising:
immersing at least a portion of the photovoltaic cell in a conversion reagent,
illuminating at least a portion of the immersed photovoltaic cell with a suitable source of illumination, and
applying an appropriate electrical bias voltage on the immersed photovoltaic cell.

2. The method of claim 1, comprising using an electrolyte which increases the resistivity of the electrode near the performance reducing shunt when the electrical bias voltage is applied in a preferred range, while the change in resistivity is substantially smaller outside of the bias voltage range.

3. The method of claim 2, comprising illuminating with a light of a wavelength which activates the thin film semiconductor layer and causes production of a photovoltage.

4. The method of claim 3, comprising illuminating light with a suitable wavelength and a sufficient intensity whereby the photovoltage produced by the illumination in an unshunted region inhibits the increase of the resistivity of the electrode material in the unshunted regions.

5. The method of claim 4, wherein the electrode is a transparent and electrically conductive material which is superposed on an illumination side of the semiconducting layer.

6. The method of claim 5, wherein the transparent, electrically conducting material comprises indium-tin oxide (ITO), indium oxide, tin oxide and other doped or alloyed variations of these oxide materials.

7. The method of claim 6, wherein the thin film semiconductor layers for the photovoltaic device comprise at least one of amorphous silicon, amorphous germanium, microcrystalline silicon, nanocrystalline silicon or their alloys.

8. The method of claim 1, wherein the electrolyte comprises an aqueous solution of aluminum chloride (AlCl₃).

9. The method of claim 7, wherein the photovoltaic device comprises a triple junction solar cell comprising at least one of amorphous silicon, amorphous germanium, microcrystalline silicon, nanocrystalline silicon or their alloys.

10. The method of claim 4, wherein the electrode is on a backside of the semiconductor layers, opposite to an illumination-entering side.

11. The method of claim 10, wherein the semiconductor layers are illuminated from the illumination-entering side during the passivation process.

12. The method of claim 11, wherein the electrode comprises at least one of a transparent oxide layer or a thin metal layer.

13. The method of claim 4, wherein the surface of the electrode is partially or fully illuminated without restricting the illumination to only the shunted regions or near the shunted regions.

14. The method of claim 1, wherein a front surface of the photovoltaic cell is illuminated by a tungsten halogen lamp, and wherein the electrical bias of from approximately 1 to approximately 4 volts is applied between the counter-electrode which comprises an aluminum mesh that allows the passage of light, and steel electrode for a suitable period of time of from approximately 1 to approximately 30 seconds and electrolyte conductivity of from approximately 0.2 to approximately 100 mS/cm.

15. The method of claim 4, wherein a front surface of the photovoltaic cell is illuminated by a tungsten halogen lamp, and wherein an electrical bias of from approximately 1 to approximately 4 volts is applied between the counter-electrode which comprises an aluminum mesh that allows the passage of light, and steel electrode for a suitable period of time of 1-30 s and electrolyte conductivity of from approximately 0.2 to approximately 100 mS/cm.

16. The method of claim 4, wherein the passivation is carried out in two or more steps, each step having different passivation conditions which are optimal for shunts having different shunt resistances.

17. The method of claim 16, wherein the passivation is carried out in two steps, each step employing a different voltage bias.

18. The method of claim 17, wherein the first passivation step is carried out with a first bias voltage and the second passivation step is carried out with a second bias voltage, wherein the first voltage is smaller than the second voltage.

19. The method of claim 4, wherein the bias voltage is changed smoothly during shunt passivation.

20. An apparatus for performing the light-assisted shunt passivation in a photovoltaic cell, the apparatus comprising: an electrolyte, a counter-electrode, and a conducting electrode placed in near or in contact with the photovoltaic cell.

21. The apparatus of claim 20, further including a source of illumination positioned in opposing relationship to the conducting electrode.

22. The apparatus of claim 21, wherein the illumination source comprises wavelengths which activate the thin film semiconductor layers.

23. The apparatus of claim 20, further including a voltage ramp for substantially smoothly changing the bias voltage during shunt passivation.

24. A photovoltaic device made using the method of the claim 1.

25. A photovoltaic device made using the apparatus of the claim 1.
